(19) United States
(12) Patent Application Publication
(10) Pub. No.: US 2003/0011079 A1
(43) Pub. Date: Jan. 16, 2003

(54) Semiconductor device and method of fabricating the same

(75) Inventors: Keizo Takano, Hyogo (JP); Takuma Tamura, Hyogo (JP); Yasushi Imazawa, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/117,214

(22) Filed: Apr. 8, 2002

(30) Foreign Application Priority Data
Jul. 16, 2001 (JP) 2001-215418(P)

(51) Int. Cl. H01L 23/495; H01L 23/48; H01L 23/52; H01L 29/40; H01L 23/28; H01L 23/29

(52) U.S. Cl. 257/790; 257/787; 257/666; 257/788; 257/784

(57) ABSTRACT

A semiconductor device in which electric contact between a semiconductor chip and a wire is suppressed and a method of fabricating the same are attained. An insulating tape is adhered between a conductive deposit made of aluminum or the like and a wire so as to cover a corner portion on a main surface side to which a wire is connected of a semiconductor chip. Consequently, even if there is a conductive deposit (metal piece or the like) in the corner portion on the main surface side to which wire is connected of semiconductor chip, which is scattered when the semiconductor wafer is diced, occurrence of a short circuit between the semiconductor chip and the wire due to contact between the wire and the conductive deposit is suppressed.

### BACKGROUND OF THE INVENTION

1. Field of the Invention

The present invention relates to a semiconductor device having a structure in which electric contact between a semiconductor chip and a bonding wire is suppressed, and a method of fabricating a semiconductor device, capable of suppressing electric contact between a semiconductor chip and a wire.

2. Description of the Background Art

In recent years, to realize a thinner semiconductor device, a loop of bonding wire has been made tighter (, or less slack). On the other hand, at the time of dicing a wafer into semiconductor chips, in some cases, a metal portion on a dicing line is caught in a dicer, the caught metal portion is scattered as a metal piece, and the metal piece remains as a deposit on a side face or at an end portion of the top face of a semiconductor chip.

In the thinner semiconductor device, as shown in FIG. 15, the clearance between the bonding wire with tighter loop and the semiconductor chip is narrower, so that the possibility that the bonding wire and the semiconductor chip come into electrical contact with each other by a metal piece deposited on the semiconductor chip increases. When the bonding wire and the semiconductor chip come into electrical contact with each other, a problem such as generation of a leak current occurs in the semiconductor device. Consequently, for the thinner semiconductor device, means for preventing contact between the bonding wire and the semiconductor chip has to be provided.

### SUMMARY OF THE INVENTION

An object of the invention is to provide a semiconductor device having a structure in which electric contact between a semiconductor chip and a bonding wire is suppressed and a method of fabricating a semiconductor device, capable of suppressing electric contact between a semiconductor chip and a bonding wire.

A semiconductor device according to a first aspect of the invention includes: a semiconductor chip including a conductive layer; a wire electrically connected to the semiconductor chip; an outside connection terminal electrically connected to the wire, positioned on the side of a side face of the semiconductor chip, and electrically connected to an external terminal; and an insulating tape covering a corner portion on a main surface side to which the wire is connected of the semiconductor chip.

With such a structure, even if there is a conductive deposit in the corner portion on the main surface side to which a wire is connected of semiconductor chip, which is scattered when the semiconductor chip including the conductive layer is formed by dicing the semiconductor wafer, the conductive deposit is covered with the insulating tape. Consequently, occurrence of a short circuit between the semiconductor chip and the wire due to contact between the wire and the conductive deposit can be suppressed.

A semiconductor device according to a second aspect of the invention includes: a semiconductor chip including a conductive layer; a wire electrically connected to the semiconductor chip; and an outside connection terminal electrically connected to the wire, positioned on the side of a side face of the semiconductor chip, and electrically connected to an external terminal, and a corner portion on a main surface side to which the wire is connected of the semiconductor chip is removed.

With such a structure, the semiconductor device can be formed by using the fabricating method such that even if there is a conductive deposit in the corner portion on the main surface side to which a wire is connected of semiconductor chip, which is scattered when the semiconductor chip including the conductive layer is formed by dicing the semiconductor wafer, the conductive deposit is removed when the corner portion is removed. Thus, occurrence of a short circuit between the semiconductor chip and the wire can be suppressed.

A semiconductor device according to a third aspect of the invention has: a semiconductor chip including a conductive layer; a wire electrically connected to the semiconductor chip; an outside connection terminal electrically connected to the wire, positioned on the side of a side face of the semiconductor chip, and connected to an external terminal; and a die bonding resin covering a corner portion on a main surface side to which the wire is connected of the semiconductor chip.

With such a structure, even if there is a conductive deposit in the corner portion on the main surface side to which a wire is connected of semiconductor chip, which is scattered when the semiconductor chip including the conductive layer is formed by dicing the semiconductor wafer, the conductive deposit is covered with the die bonding resin. Consequently, occurrence of a short circuit between the semiconductor chip and the wire due to contact between the wire and the conductive deposit can be suppressed.

A method of fabricating a semiconductor device according to a first aspect of the invention includes: a step of forming a semiconductor chip by dicing a semiconductor wafer including a conductive layer; a step of forming a wire electrically connected to the semiconductor chip; and a method of forming an outside connection terminal electrically connected to the wire, positioned on the side of a side face of the semiconductor chip, and connected to an external terminal. In the method, after the step of forming the semiconductor chip and before the step of forming the wire, a step of adhering an insulating tape so as to cover a corner portion on a main surface side to which the wire is connected of the semiconductor chip is provided.

With such a fabricating method, in the step of forming the semiconductor chip by dicing the semiconductor wafer, even if pieces of the conductive layer are scattered and each of the scattered pieces remains as a conductive deposit in the corner portion on the main surface side to which a wire is connected of semiconductor chip, the insulating tape can be adhered on the conductive deposit. Consequently, the semiconductor device in which occurrence of a short circuit between the semiconductor chip and the wire due to contact between the wire and the conductive deposit is suppressed can be fabricated.

In the method of fabricating a semiconductor device according to the first aspect of the invention, the insulating tape is in a paste state and is applied. By such a fabricating method, the insulating tape can be easily adhered.

A method of fabricating a semiconductor device according to a second aspect of the invention includes: a step of forming a semiconductor chip by dicing a semiconductor wafer including a conductive layer; a step of forming a wire electrically connected to the semiconductor chip; and a step of forming an outside connection terminal electrically connected to the wire, positioned on the side of a side face of the semiconductor chip, and electrically connected to an external terminal, in which after the step of dicing the semiconductor chip and before the step of forming the wire, a step of removing a corner portion on a main surface side to which the wire is connected of the semiconductor chip is provided.

With such a fabricating method, in the step of forming the semiconductor chip by dicing the semiconductor wafer, even if pieces of the conductive layer are scattered and each of the scattered pieces remains as a conductive deposit in the corner portion on the main surface side to which a wire is connected of semiconductor chip, the conductive deposit can be removed when the corner portion of the semiconductor chip is removed. Consequently, the semiconductor device in which occurrence of a short circuit between the semiconductor chip and the wire due to contact between the wire and the conductive deposit is suppressed can be fabricated.

In the method of fabricating a semiconductor device according to the second aspect of the invention, preferably, in the step of removing the corner portion, two semiconductor chips are arranged with a gap, and corner portions of the semiconductor chips are simultaneously removed by a polisher.

By employing the fabricating method, the corner portions of two semiconductor chips can be simultaneously removed by a single removing step. Thus, the fabricating process can be simplified.

A method of fabricating a semiconductor device according to a third aspect of the invention includes: a step of forming a semiconductor chip by dicing a semiconductor wafer including a conductive layer; a step of forming a wire electrically connected to the semiconductor chip; and a step of forming an outside connection terminal electrically connected to the wire, positioned on the side of a side face of the semiconductor chip, and electrically connected to an external terminal, in which after the step of forming the semiconductor chip, a step of applying a die bonding resin so as to cover a corner portion on a main surface side to which the wire is connected of the semiconductor chip is provided.

With such a fabricating method, in the step of forming the semiconductor chip by dicing the semiconductor wafer, even if pieces of the conductive layer are scattered and each of the scattered pieces remains as a conductive deposit in the corner portion on the main surface side to which a wire is connected of semiconductor chip, the die bonding resin can be applied on the conductive deposit. Consequently, the semiconductor device in which occurrence of a short circuit between the semiconductor chip and the wire due to contact between the wire and the conductive deposit is suppressed can be fabricated.

A method of fabricating a semiconductor device according to a fourth aspect of the invention includes: a step of forming a semiconductor chip by dicing a semiconductor wafer including a conductive layer; a step of forming a wire electrically connected to the semiconductor chip; and a method of forming an outside connection terminal electrically connected to the wire, positioned on the side of a side face of the semiconductor chip, and connected to an external terminal, in which simultaneously with or after the dicing step, the semiconductor chip is cleaned ultrasonically.

With such a fabricating method, in the step of dicing the semiconductor wafer, even if pieces of the conductive layer are scattered and each of the scattered pieces remains as a conductive deposit in the corner portion on the main surface side to which a wire is connected of semiconductor chip, the conductive deposit is removed by ultrasonic cleaning. Thus, occurrence of a short circuit between the semiconductor chip and the wire is suppressed.

In the method of fabricating a semiconductor device according to the fourth aspect of the invention, preferably, in a state where the function of the conductive layer is maintained, the ultrasonic cleaning is performed to an extent that only a scattered piece of the conductive layer at the time of the dicing is removed.

According to the fabricating method, the conductive deposit can be removed without exerting an adverse influence on the conductive layer.

A method of fabricating a semiconductor device according to a fifth aspect of the invention includes: a step of forming a semiconductor chip by dicing a semiconductor wafer including a conductive layer; a step of forming a wire electrically connected to the semiconductor chip; and a step of forming an outside connection terminal electrically connected to the wire, positioned on the side of a side face of the semiconductor chip, and connected to an external terminal, in which simultaneously with or after the dicing step, a fluid is injected to the semiconductor chip.

With such a fabricating method, in the step of dicing the semiconductor wafer, even if pieces of the conductive layer are scattered and each of the scattered pieces remains as a conductive deposit in the corner portion on the main surface side to which a wire is connected of semiconductor chip, the conductive deposit can be removed by injection of a fluid. Consequently, occurrence of a short circuit between the semiconductor chip and the wire can be suppressed.

In the method of fabricating a semiconductor device according to the fifth aspect of the invention, the step of injecting the fluid to the semiconductor chip is performed before the step of forming the wire.

With such a fabricating method, the conductive deposit can be removed without exerting an adverse influence on the wire.

In the method of fabricating a semiconductor device according to the fifth aspect of the invention, the fluid may be air.

With such a fabricating method, the conductive deposit can be removed without exerting an adverse influence on the semiconductor chip.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross section of a semiconductor device according to a first embodiment;

FIG. 2 is a process drawing for explaining a method of fabricating the semiconductor device according to the first embodiment;

FIG. 3 is a process drawing for explaining the method of fabricating the semiconductor device according to the first embodiment;

FIG. 4 is a process drawing for explaining the method of fabricating the semiconductor device according to the first embodiment;

FIG. 5 is a process drawing for explaining the method of fabricating the semiconductor device according to the first embodiment;

FIG. 6 is a process drawing for explaining the method of fabricating the semiconductor device according to the first embodiment;

FIG. 7 is a cross section of a semiconductor device according to a second embodiment;

FIG. 8 is a process drawing for explaining a method of fabricating the semiconductor device according to the second embodiment;

FIG. 9 is a cross section of a semiconductor device according to a third embodiment;

FIG. 10 is a process drawing for explaining a method of fabricating the semiconductor device according to the third embodiment;

FIG. 11 is a process drawing for explaining the method of fabricating the semiconductor device according to the third embodiment;

FIG. 12 is a process drawing for explaining a method of fabricating a semiconductor device according to a fourth embodiment;

FIG. 13 is a process drawing for explaining the method of fabricating the semiconductor device according to the fourth embodiment;

FIG. 14 is a process drawing for explaining a method of fabricating a semiconductor device according to a fifth embodiment; and

FIG. 15 is a cross section of a conventional semiconductor device.

### DESCRIPTION OF THE PREFERRED EMBODIMENTS

Embodiments of the invention will be described hereinbelow with reference to the drawings.

### First Embodiment

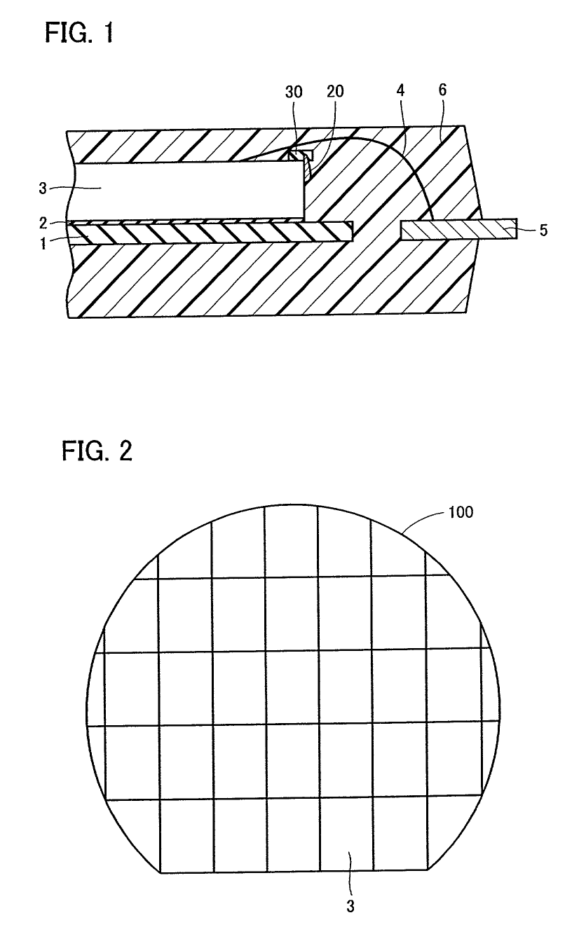

A semiconductor device according to a first embodiment of the invention will be described by referring to FIG. 1. In the semiconductor device of the embodiment, a semiconductor chip 3 in which a conductive layer such as an aluminum wiring layer is formed is formed on a die pad 1 via a bonding material 2. A wire 4 is electrically connected to the wiring layer made of aluminum or the like in semiconductor chip 3. Near a side face of semiconductor chip 3, an inner lead 5 as an outside connection terminal electrically connected to both wire 4 and an external terminal is provided. At a corner on the main surface side to which wire 4 is connected of semiconductor chip 3, a conductive deposit 20 made of aluminum or the like exists. An insulating tape 30 is adhered between conductive deposit (metal piece) 20 made of aluminum or the like and wire 4 so as to cover the corner on the main surface side to which wire 4 is connected of semiconductor chip 3. Further, die pad 1, bonding material 2, semiconductor chip 3, wire 4, and a part of inner lead 5 as the terminal for connection to the outside are covered with a resin 6 such as epoxy resine.

With such a structure, even if there is conductive deposit (metal piece or the like) 20 in the corner portion on the main surface side to which wire 4 is connected of semiconductor chip 3, which is scattered when the conductive layer such as aluminum wiring layer is cut at the time of dicing the semiconductor wafer into semiconductor chips 3, because of insulating tape 30 provided between deposit 20 and wire 4, it is suppressed that wire 4 and deposit 20 come into contact with each other to cause a short circuit between semiconductor chip 3 and wire 4.

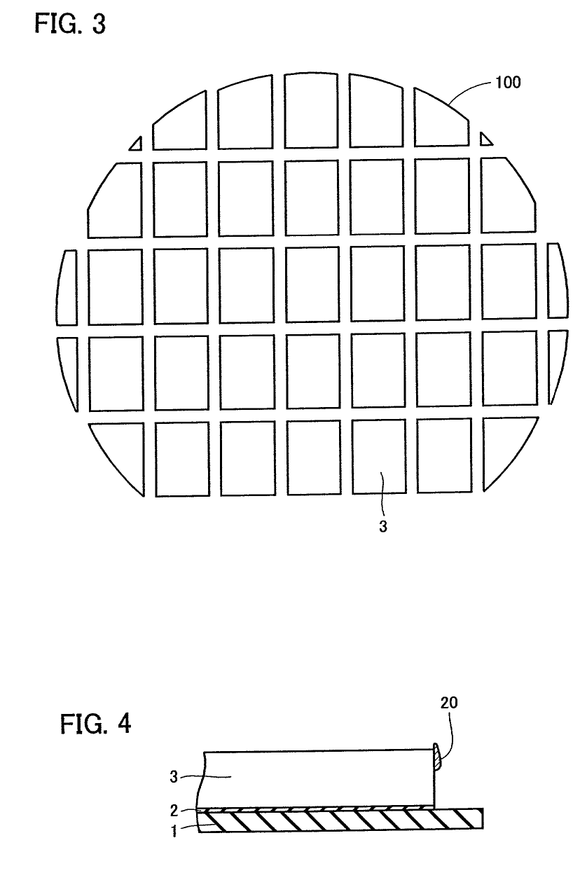

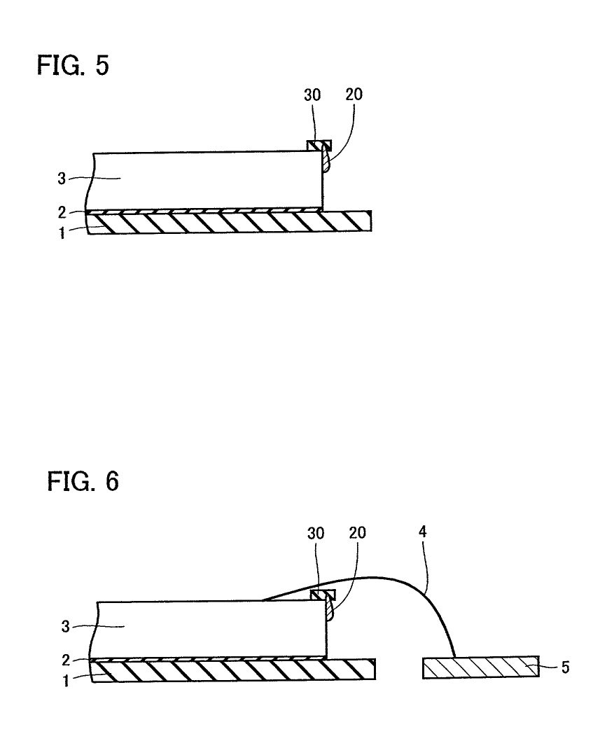

A method of fabricating the semiconductor device of the embodiment will now be described by referring to FIGS. 2 to 6. The method of fabricating the semiconductor device of the embodiment is a generally known method. First, a semiconductor wafer 100 including a conductive layer such as an aluminum wiring layer shown in FIG. 2 is diced into a plurality of semiconductor chips 3 as shown in FIG. 3. Each of semiconductor chips 3 is taken out. At this time, in a corner portion and the like of the main surface of semiconductor chip 3, conductive deposit 20 of aluminum wiring layer or the like scattered at the time of dicing semiconductor wafer 100 exists. As shown in FIG. 4, semiconductor chip 3 is fixed on die pad 1 via bonding material 2. As shown in FIG. 5, by adhering insulating tape 30 on the corner portion on the main surface side to which wire 4 is connected of semiconductor chip 3, deposit 20 is covered with insulating tape 30, thereby preventing deposit 20 and wire 4 to be formed next from coming into contact with each other. As shown in FIG. 6, wire 4 is electrically connected to semiconductor chip 3 and inner lead 5 as an outside connection terminal positioned on the side of a side face of semiconductor chip 3 and to be connected to an external terminal.

By such a fabricating method, in the process of dicing semiconductor wafer 100 into semiconductor chips 3 shown in FIGS. 2 and 3, even if pieces of the conductive layer such as aluminum wiring layer are scattered and each of the scattered pieces remains as conductive deposit 20 in the corner portion on the main surface side to which wire 4 is connected of semiconductor chip 3, since insulating tape 30 is adhered on deposit 20, the semiconductor device in which occurrence of a short circuit between semiconductor chip 3 and wire 4 due to the contact between wire 4 and conductive deposit 20 is suppressed can be fabricated. In the method of fabricating the semiconductor device of the embodiment, by applying insulating tape 30 in a paste state, insulating tape 30 is easily adhered to semiconductor chip 3. According to the method of fabricating the semiconductor device of the embodiment, insulating tape 30 is just adhered. Consequently, by applying paste-state insulating tape 30 only to positions where deposits 20 are adhered, insulating tape 30 can be effectively adhered to semiconductor chip 3.

### Second Embodiment

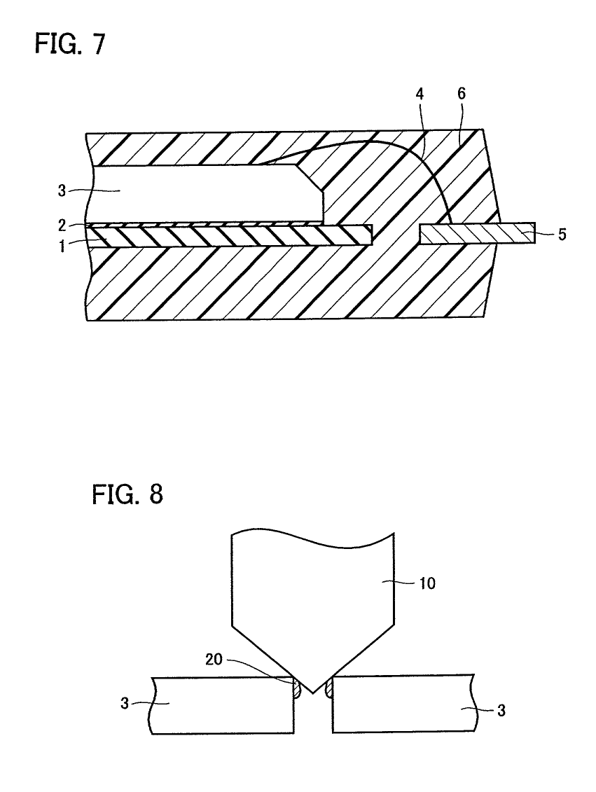

A semiconductor device according to a second embodiment will now be described with reference to FIG. 7. As shown in FIG. 7, the semiconductor device of the second embodiment has a structure similar to that of the semiconductor device of the first embodiment shown in FIG. 1 except that insulating tape 30 as illustrated in FIG. 5 is not adhered and the corner portion of the main surface side to which wire 4 is connected of semiconductor chip 3 is removed. Even if there is conductive deposit 20 which is a piece of an aluminum wiring layer or the like scattered when the semiconductor wafer is diced into semiconductor chips 3 in the corner portion on the main surface side to which wire 4 is connected of semiconductor chip 3, conductive deposit 20 can be also removed when the corner portion is removed. Thus, occurrence of a short circuit between semiconductor chip 3 and wire 4 is suppressed.

A method of fabricating the semiconductor device of the embodiment will now be described by referring to FIG. 8. The method of fabricating the semiconductor device of the second embodiment is similar to that of the semiconductor device of the first embodiment described with reference to FIGS. 2 to 6 except for the following. After the dicing process to form semiconductor chips 3 shown in FIGS. 2 and 3 and before the process of forming wire 4 shown in FIG. 6, in place of the process of adhering insulating tape 30 shown in FIG. 5, a process of polishing and removing the corner portion on the main surface side to which wire 4 is connected of semiconductor chip 3 by a polisher 10 as shown in FIG. 8 is provided.

By using the fabricating method, even if pieces of the conductive layer such as an aluminum wiring layer are scattered and each piece remain as conductive deposit 20 as shown in FIG. 4 in the corner portion on the main surface side to which wire 4 is connected of semiconductor chip 3 in the process of forming semiconductor chip 3 by dicing semiconductor wafer 100 shown in FIGS. 2 and 3, conductive deposit 20 can be polished so as to be removed by polisher 10 having wedge-shaped teeth. Consequently, the semiconductor device in which occurrence of a short circuit between semiconductor chip 3 and wire 4 caused by contact between wire 4 and conductive deposit 20 is suppressed can be fabricated. According to the method of fabricating the semiconductor device of the embodiment, the process of removing the corner portion is performed by disposing two semiconductor chips 3 with a gap and simultaneously polishing the corners of the chips by polisher 10. Since the corners of two semiconductor chips 3 can be simultaneously removed by a single removing process, the fabricating process can be simplified.

### Third Embodiment

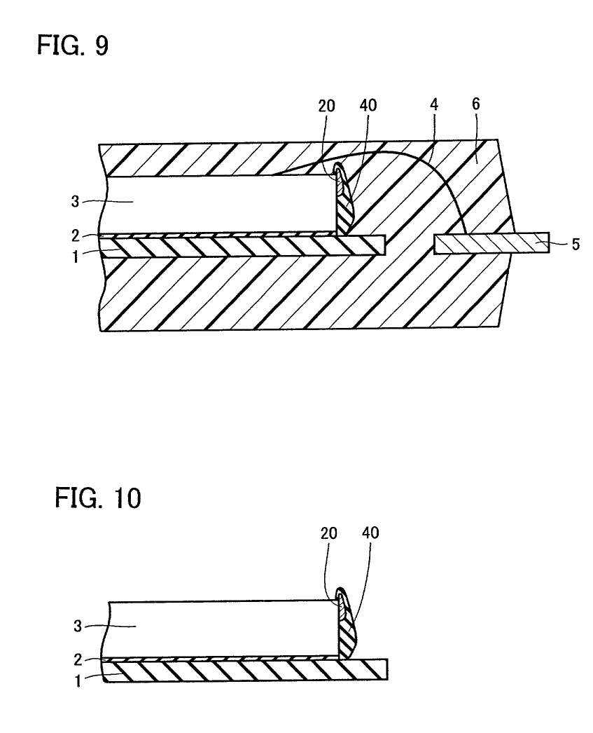

The structure of a semiconductor device according to a third embodiment will be described with reference to FIG. 9. The semiconductor device of the third embodiment has a structure similar to that of the semiconductor device described by referring to FIG. 1 except for the following. In place of adhering insulating tape 30 shown in FIG. 5, a die bonding resin 40 covering deposit 20 and the corner portion on the main surface side to which wire 4 is connected of semiconductor chip 3 is formed so as to cover the aluminum wiring layer.

With such a structure, even if there is conductive deposit 20 in the corner portion on the main surface side to which wire 4 is connected of semiconductor chip 3, which is spread when the semiconductor wafer shown in FIGS. 2 and 3 is diced into semiconductor chips 3 each including the conductive layer such as an aluminum wiring layer, conductive deposit 20 is covered with die bonding resin 40. Consequently, occurrence of a short circuit between semiconductor chip 3 and wire 4 due to contact between wire 4 and conductive deposit 20 can be suppressed.

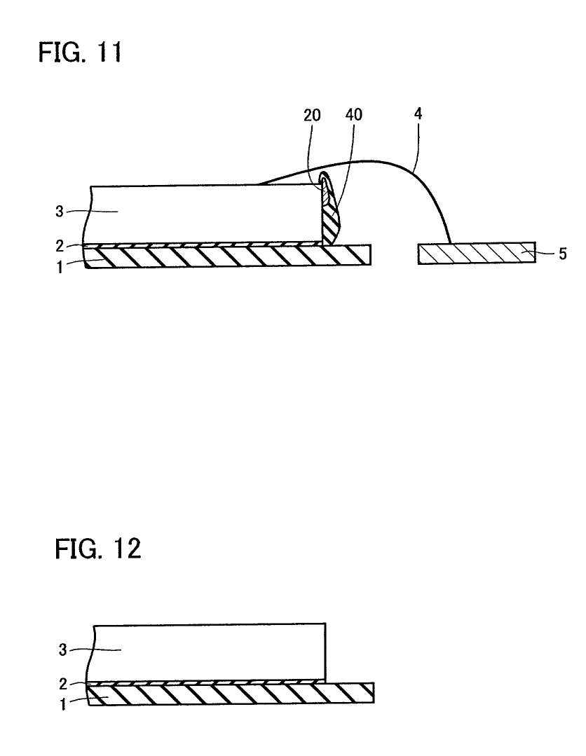

The method of fabricating the semiconductor device of the embodiment will now be described by referring to FIGS. 10 and 11. The method of fabricating the semiconductor device of the third embodiment is similar to that of the semiconductor device of the first embodiment described by referring to FIGS. 2 to 6 except for the following. After the process of forming semiconductor chip 3 shown in FIG. 3, in place of the process of adhering insulating tape 30 shown in FIG. 5, a process of applying die bonding resin 40 covering the corner portion on the main surface side to which wire 4 is connected of semiconductor chip 3 so as to cover the aluminum wiring layer as shown in FIG. 10 is provided. After the process of applying die bonding resin 40, as shown in FIG. 11, in a manner similar to the method of fabricating the semiconductor device of the first embodiment, a process of electrically connecting the wire 4 to both semiconductor chip 3 and electrode 5 for connection to the outside is provided.

By employing such a fabricating method, even if pieces of the conductive layer such as an aluminum layer are scattered in the process of dicing semiconductor wafer 100 shown in FIGS. 2 and 3 into semiconductor chips 3 and each piece remains as conductive deposit 20 in the corner portion on the main surface side to which wire 4 is connected of semiconductor chip 3 as shown in FIG. 4, die bonding resin 40 is applied on conductive deposit 20. Consequently, the semiconductor device in which occurrence of a short circuit between semiconductor chip 3 and wire 4 due to contact between wire 4 and conductive deposit 20 is suppressed can be fabricated.

### Fourth Embodiment

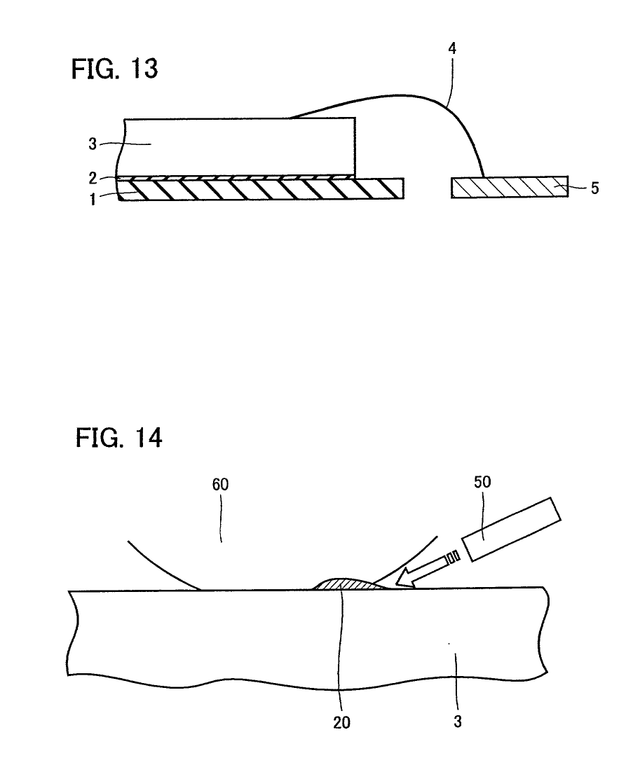

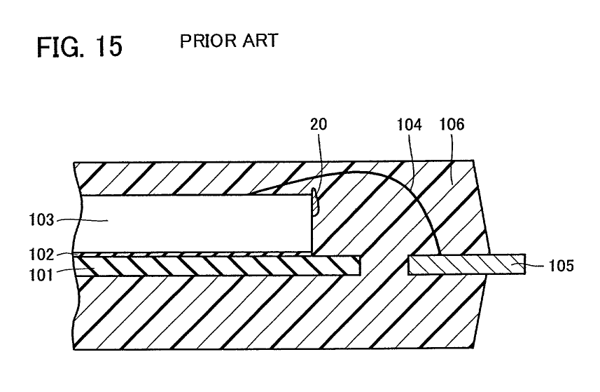

A method of fabricating a semiconductor device according to a fourth embodiment will be described by referring to FIGS. 12 and 13. The method of fabricating the semiconductor device of the fourth embodiment is similar to that of the semiconductor device of the first embodiment described by referring to FIGS. 2 to 6 except that semiconductor chip 3 is subjected to ultrasonic cleaning simultaneously with or after the dicing process shown in FIGS. 2 and 3. Therefore, conductive deposit 20 as shown in FIG. 4 is removed, and the structure as shown in FIG. 12 is formed. After that, in a manner similar to the method of fabricating the semiconductor device of the first embodiment, wire 4 is formed, and the structure as shown in FIG. 13 is obtained.

By employing such a fabricating method, even if pieces of the conductive layer such as an aluminum wiring layer are scattered in the process of dicing semiconductor wafer 100 shown in FIGS. 2 and 3 and each of the scattered pieces becomes conductive deposit 20 in the corner portion on the main surface side to which wire 4 is connected of semiconductor chip 3, conductive deposit 20 is removed by ultrasonic cleaning as shown in FIGS. 12 and 13. Consequently, the semiconductor device having the structure in which occurrence of a short circuit between semiconductor chip 3 and wire 4 is suppressed can be fabricated.

According to the method of fabricating the semiconductor device of the embodiment, in a state where the function of the conductive layer such as an aluminum wiring layer is maintained, ultrasonic cleaning is performed to an extent that only the piece of the conductive layer, which is scattered in the dicing operation shown in FIGS. 2 and 3 is removed. Consequently, conductive deposit 20 shown in FIG. 40 can be removed without exerting an adverse influence on the conductive layer such as aluminum wiring layer.

### Fifth Embodiment

A method of fabricating a semiconductor device according to a fifth embodiment will be described by referring to FIG. 14. The method of fabricating the semiconductor device of the fifth embodiment is similar to that of the semiconductor device of the embodiment shown in FIGS. 2 to 6 except that, simultaneously with or after the dicing process using a dicing saw 60 as shown in FIGS. 2 and 3, a fluid is injected by an injector 50 to semiconductor chip 3 as shown in FIG. 14.

By employing such a fabricating method, even if pieces of the conductive layer such as an aluminum wiring layer are scattered in the process of dicing semiconductor wafer 100 shown in FIGS. 2 and 3 and each of the scattered pieces remains as conductive deposit 20 in the corner portion on the main surface side to which wire 4 is connected of semiconductor chip 3 as shown in FIG. 4, conductive deposit 20 is removed by injection of a fluid. Consequently, occurrence of a short circuit between semiconductor chip 3 and wire 4 is suppressed.

According to the method of fabricating the semiconductor device of the embodiment, the process of injecting a fluid to semiconductor chip 3 shown in FIG. 14 is performed prior to the process of forming wire 4 shown in FIG. 6. Thus, conductive deposit 20 can be removed without exerting an adverse influence on wire 4.

In the method of fabricating the semiconductor device of the embodiment, the fluid may be air or liquid. Consequently, conductive deposit 20 can be removed without exerting an adverse influence on semiconductor chip 3.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a semiconductor chip including a conductive layer;
a wire electrically connected to the semiconductor chip;
an outside connection terminal electrically connected to the wire, positioned on the side of a side face of said semiconductor chip, and electrically connected to an external terminal; and
an insulating tape covering a corner portion on a main surface side to which said wire is connected of said semiconductor chip.

2. A semiconductor device comprising:
a semiconductor chip including a conductive layer;
a wire electrically connected to the semiconductor chip; and
an outside connection terminal electrically connected to the wire, positioned on the side of a side face of said semiconductor chip, and electrically connected to an external terminal,
wherein a corner portion on a main surface side to which said wire is connected of said semiconductor chip is removed.

3. A semiconductor device comprising:
a semiconductor chip including a conductive layer;
a wire electrically connected to the semiconductor chip;
an outside connection terminal electrically connected to the wire, positioned on the side of a side face of said semiconductor chip, and connected to an external terminal; and
a die bonding resin covering a corner portion on a main surface side to which said wire is connected of said semiconductor chip.
